(19) United States
(12) Patent Application Publication
(10) Pub. No.: US 2024/0270778 A1
(43) Pub. Date: Aug. 15, 2024

(54) NOVEL HAFNIUM-CONTAINING COMPOUND, HAFNIUM PRECURSOR COMPOSITION CONTAINING SAME, HAFNIUM-CONTAINING THIN FILM USING HAFNIUM PRECURSOR COMPOSITION, AND PREPARATION METHOD THEREFOR

(71) Applicant: ICHEMS CO., LTD., Hwaseong-si, Gyeonggi-do (KR)

(72) Inventors: Hyun Chang KIM, Hwaseong-si, Gyeonggi-do (KR); Hyung Soo SHIN, Hwaseong-si, Gyeonggi-do (KR); Doo Hun LEE, Hwaseong-si, Gyeonggi-do (KR); Chul Hee KWON, Hwaseong-si, Gyeonggi-do (KR)

(21) Appl. No.: 18/562,334

(22) PCT Filed: May 11, 2022
(86) PCT No.: PCT/KR2022/006709

§ 371 Date: Nov. 20, 2023

(30) Foreign Application Priority Data
May 21, 2021 (KR) 10-2021-0065659

(51) Int. Cl. C07F 17/00; C23C 16/40; C23C 16/455

(52) U.S. Cl. CPC C07F 17/00; C23C 16/405; C23C 16/45553

(57) ABSTRACT

The present invention relates to a hafnium-containing precursor that can be used in the formation of various hafnium-containing thin films, wherein the hafnium-containing precursor is liquid at room temperature and exhibits high volatility and high thermal stability and thus can be used in a high-quality hafnium-containing thin film and a preparation method therefor.

### TECHNICAL FIELD

The present disclosure relates to a novel hafnium-containing compound, a hafnium precursor composition containing the hafnium-containing compound, a hafnium-containing thin film formed by using the hafnium precursor composition, and a method of forming the hafnium-containing thin film.

### BACKGROUND ART

Capacitance is proportional to the dielectric constant of a dielectric and the area of a capacitor and is inversely proportional to the thickness of a dielectric. To increase capacitance, it is required to develop a method of structurally increasing the area of a capacitor or reducing the thickness of a dielectric as well as a material with a high dielectric constant. A cylindrical-shaped capacitor is used to increase the area, but the capacitor requires advanced etching technology and causes a tilted etch profile when the height of the capacitor is designed to be excessively large. Moreover, with the downscaling of devices, there is a problem that leakage current increases due to the tunneling effect. Therefore, there is a limit to structurally increasing the capacitance, so it is necessary to develop a precursor material for a dielectric with a high dielectric constant and thin film deposition.

Recently, oxide thin films based on Group 4 metals such as hafnium or zirconium have been actively developed. The films are widely used as high dielectric thin film materials due to the relatively wide bandgap energy, high Si integration, and high compatibility thereof. Hafnium oxide or zirconium oxide films have a high dielectric constant depending on the crystal structure of the thin films. In addition, a method in which hafnium/zirconium composite oxide films (HfZrO₂), hafnium oxide, or zirconium oxide films are doped with aluminum (Al), yttrium (Y), and lanthanum (La) in small amounts is also recently applied to improve the structural and electrical properties of thin films.

For example, Korean Patent Application Publication No. 10-2018-0132568 discloses a technology for forming a thin film containing an organic Group 4 compound by using a hafnium complex having a cyclopentadienyl group as a precursor. The hafnium compound used in the related art improves deposition efficiency by having a cyclopentadienyl group. However, since the hafnium compound is used to form a composite metal thin film with metal atoms such as aluminum, gallium, and germanium, the related art has its limits to improving the deposition rate, uniformity, flatness of the thin film, and purity, it is required to develop an improved precursor.

### DISCLOSURE

### Technical Problem

The present disclosure relates to a high dielectric constant precursor developed in consideration of the related art as described above. One objective of the present disclosure is to provide a novel hafnium compound and a hafnium precursor composition containing the hafnium compound able to be used as a precursor for a high dielectric constant thin film containing hafnium.

In addition, another objective of the present disclosure is to provide a high dielectric constant thin film formed by using the hafnium-containing precursor composition and a method of forming the same.

### Technical Solution

A hafnium compound to achieve the objectives described above may be used as a precursor to form a hafnium-containing thin film, and the compound is represented by the following Formula 1.

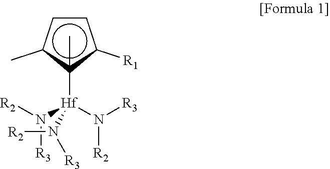

In Formula 1, R₁ is an amino group, a silyl group, an alkoxy group, or a C2-C5 alkyl group. Additionally, R₂ and R₃ are each independently an amino group, a silyl group, an alkoxy group, or a C1-C5 alkyl group.

In particular, Formula 1 may be represented by any one of the following compounds.

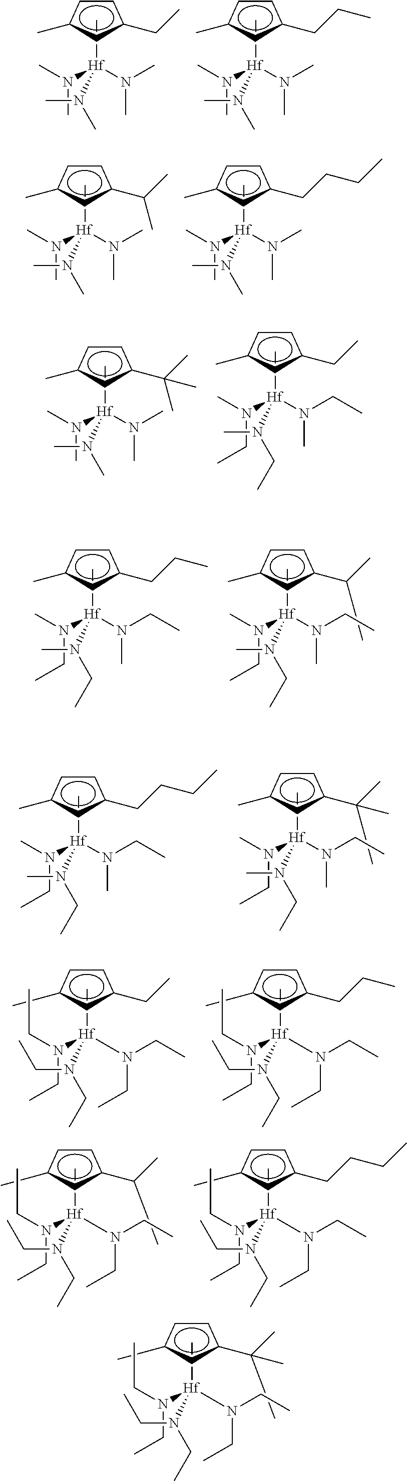

Since the hafnium compound contains a methyl group and R₁ in the cyclopentadienyl group, there is a steric hindrance effect of the cyclopentadienyl group, which inhibits the intermolecular or intramolecular interactions of the hafnium compound, resulting in higher thermal stability. As a result, the initial chemisorption rate may increase in the thin film formation process, which improves the thin film formation speed and thin film uniformity, resulting in the formation of a higher quality hafnium-containing thin film than the conventional hafnium compound having a cyclopentadienyl group.

Additionally, the hafnium-containing precursor composition of the present disclosure may include the hafnium compound.

Additionally, the thin film of the present disclosure may be formed by using the hafnium-containing compound or the hafnium-containing precursor composition.

Additionally, the method of forming the thin film may use the hafnium-containing compound or the hafnium-containing precursor composition.

Additionally, the method of forming the thin film may use a mixture of the hafnium compounds.

In addition, the hafnium-containing thin film and the method of forming the thin film are respectively formed and implemented by depositing the hafnium-containing precursor composition or the hafnium compound on a substrate in which the deposition is performed through any one of plasma-enhanced chemical vapor deposition, thermal chemical vapor deposition, plasma-enhanced atomic layer deposition, and thermal atomic layer deposition.

In addition, the method of forming the thin film includes a first step of cleaning the substrate and treating the surface of the substrate, a second step of mounting the substrate in a chamber and heating the substrate, a third step of forming a monolayer on the substrate by using the hafnium-containing compound or the hafnium-containing precursor composition, a fourth step of forming a hafnium-containing thin film by supplying reactants, and a fifth step of purging unreacted reactants.

In addition, it may further include a process of depositing a metal precursor different from the hafnium-containing compound or the hafnium-containing precursor composition on the substrate.

Additionally, the substrate may have a heating temperature in the range of 100° C. to 800° C.

In addition, the reactants may include any one or a gaseous mixture of O₂, O₃, H₂O, NO, NO₂, N₂O, H₂O₂, H₂, NH₃, alkylamine, hydrazine derivative, SiH₄, Si₂H₆, BH₃, B₂H₆, amine-borane complex, GeH₄, and PH₃.

### Advantageous Effects

A hafnium-containing precursor composition of the present disclosure is liquid at room temperature and exhibits excellent volatility and thermal stability, making it very effective in forming a high-purity hafnium-containing thin film.

In addition, due to the high thermal stability, the temperature range for a wide atomic layer deposition process can be realized, so the effect of forming the high-purity crystalline hafnium-containing thin film can be achieved.

### DESCRIPTION OF DRAWINGS

FIG. 1 shows the result of the ¹H-NMR analysis of (ethylmethylcyclopentadienyl)(trisdimethylamino)hafnium prepared in Example 1;

FIG. 2 shows the result of measuring the vapor pressure of (ethylmethylcyclopentadienyl)(trisdimethylamino)hafnium prepared in Example 1;

FIG. 3 shows the result of thermogravimetric analysis (TGA) of (ethylmethylcyclopentadienyl)(trisdimethylamino)hafnium prepared in Example 1;

FIGS. 4A-4B show temperature range graphs (ALD Window) for the atomic layer deposition process of the (ethylmethylcyclopentadienyl)(trisdimethylamino)hafnium thin film formed in Example 2 and the (cyclopentadienyl)(trisdimethylamino)hafnium thin film formed in Comparative Example 1;

FIGS. 5A-5B show spectroscopic (XPS) images of the (ethylmethylcyclopentadienyl)(trisdimethylamino)hafnium thin film formed in Example 2 and the (cyclopentadienyl)(trisdimethylamino)hafnium-containing thin film formed in Comparative Example 1;

FIG. 6 shows scanning electron microscope (SEM) images of the thickness uniformity of the (ethylmethylcyclopentadienyl)(trisdimethylamino)hafnium thin film formed in Example 2; and

FIGS. 7A-7D show scanning probe microscope (AFM) images of the (ethylmethylcyclopentadienyl)(trisdimethylamino)hafnium thin film formed in Example 2 and the (cyclopentadienyl)(trisdimethylamino)hafnium-containing thin film formed in Comparative Example 1.

### MODE FOR DISCLOSURE

Hereinafter, the present disclosure will be described in more detail. Terms or words used in this specification and claims should not be construed as limited to their common or dictionary meanings, and they must be interpreted with meaning and concept consistent with the technical idea of the present disclosure based on the principle that the inventor(s) may appropriately define the concept of terms to explain his or her disclosure in the best way.

The hafnium-containing precursor of the present disclosure is a hafnium compound or a precursor composition containing the hafnium compound represented by the following Formula 1. The precursor is liquid at room temperature and exhibits excellent volatility and thermal stability, making it very effective in forming a high-purity hafnium-containing thin film.

In addition, due to the high thermal stability, the temperature range for a wide atomic layer deposition process may be realized, so the effect of forming the high-purity crystalline hafnium-containing thin film may be achieved.

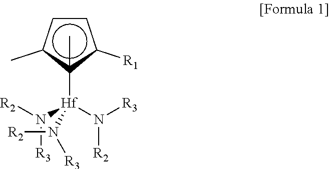

In Formula 1, R₁ is an amino group, a silyl group, an alkoxy group, or a C2-C5 alkyl group. In addition, R₂ and R₃ are each independently an amino group, a silyl group, an alkoxy group, or a C1-C5 alkyl group.

The precursor containing the hafnium-containing compound is liquid at room temperature and exhibits high volatility and thermal stability, so it may be used as a very useful precursor for forming the hafnium-containing thin film.

As used herein, the term “alkyl” refers to a straight-chain or branched saturated hydrocarbon group and includes, for example, methyl, ethyl, propyl, isobutyl, pentyl, or butyl. Additionally, C1-C5 alkyl refers to an alkyl group having 1 to 5 carbon atoms, and when C1-C5 alkyl is substituted, the carbon number of the substituted body is not included.

Specific examples of Formula 1 for forming the hafnium-containing thin film include the following chemical structures but are not limited thereto.

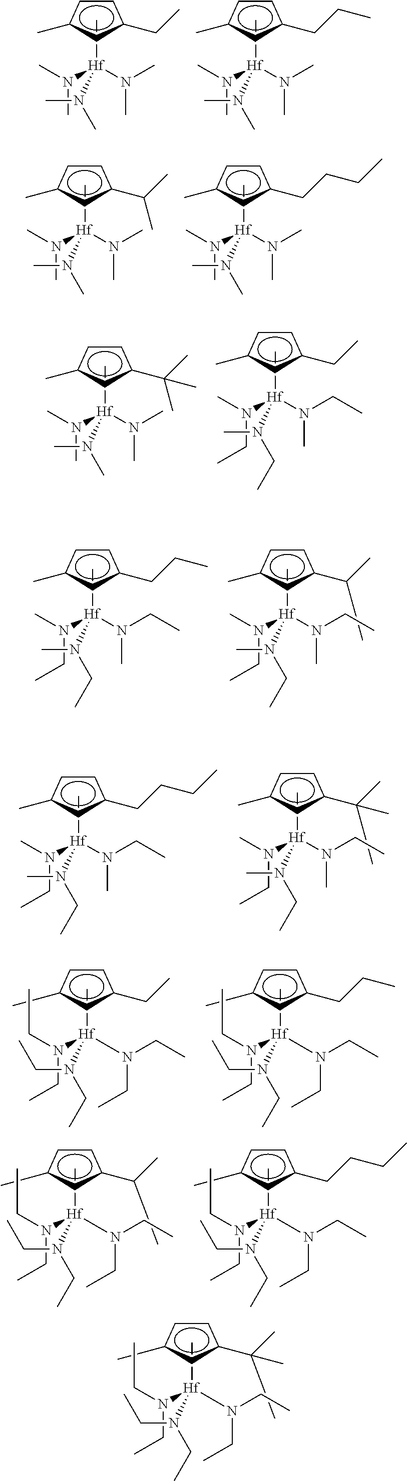

The hafnium compound may be used as a hafnium-containing precursor by itself, but may also be used in the form of a hafnium-containing precursor composition when mixed with a solvent. In the case of the precursor composition, the composition may be prepared by containing 0.1% to 99.9% by weight of the solvent based on the total weight of the composition. The solvent may be any one capable of dissolving hafnium but is preferably saturated or unsaturated hydrocarbons, cyclic ethers, acyclic ethers, esters, alcohols, cyclic amines, acyclic amines, cyclicsulfides, acyclic sulfides, phosphines, beta-diketones, or beta-keto esters.

The hafnium-containing thin film of the present disclosure may be formed by conventional methods, for example, a metal-organic chemical vapor deposition (MOCVD), an atomic layer deposition (ALD), a low-pressure chemical vapor deposition (LPCVD), a plasma-enhanced chemical vapor deposition (PECVD), or a plasma-enhanced atomic layer deposition (PEALD).

In addition, a composite metal-containing thin film containing hafnium may be formed by further depositing a metal-containing precursor different from the hafnium compound or the hafnium-containing precursor composition on the substrate. At this time, the hafnium-containing thin film which partially includes the composite metal-containing thin film may be formed by depositing at least a portion of the metal-containing precursor on one or more substrates.

The metal-containing precursor for forming the composite metal-containing thin film may be a precursor that contains an atom of one or more metals of Zr, Ti, Sc, Y, La, Ac, V, Nb, Ta, Al, Ga, In, Si,

### Ge, Sn, and Pb.

The hafnium-containing thin film formed in this way may include any one or more materials of HfO₂, HfZrOₓ, HfTiOₓ, and HfAOₓ in which the A may be any one or more of Sc, Y, La, Ac, V, Nb, Ta, Al, Ga, In, Si, Ge, Sn, and Pb.

In addition, the substrate for forming the hafnium-containing thin film may include any one or a combination of titanium nitride, titanium, boron nitride, molybdenum sulfide, molybdenum, zinc oxide, tungsten, copper, aluminum oxide, tantalum nitride, niobium nitride, silicon, silicon oxide, titanium oxide, and strontium oxide.

At this time, the substrate may preferably have a temperature in the range of 100° C. to 800° C. during the deposition, and the reaction gases may include any one or a gaseous mixture of O₂, O₃, H₂O, NO, NO₂, N₂O, H₂O₂, H₂, NH₃, alkylamine, hydrazine derivatives, SiH₄, Si₂H₆, BH₃, B₂H₆, amine-borane complex, GeH₄, and PH₃.

Hereinafter, the present disclosure will be described in more detail through examples and comparative examples.

### Example 1

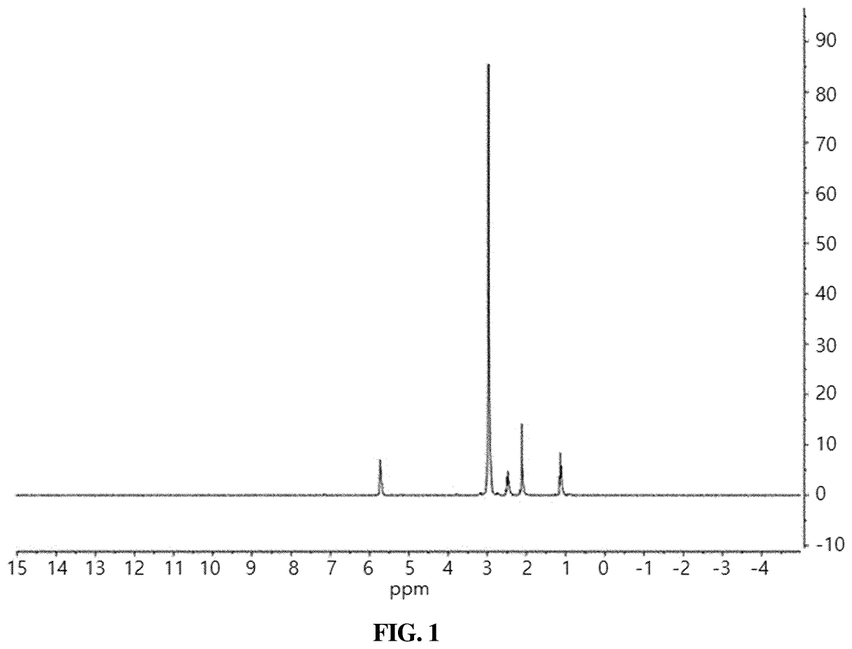

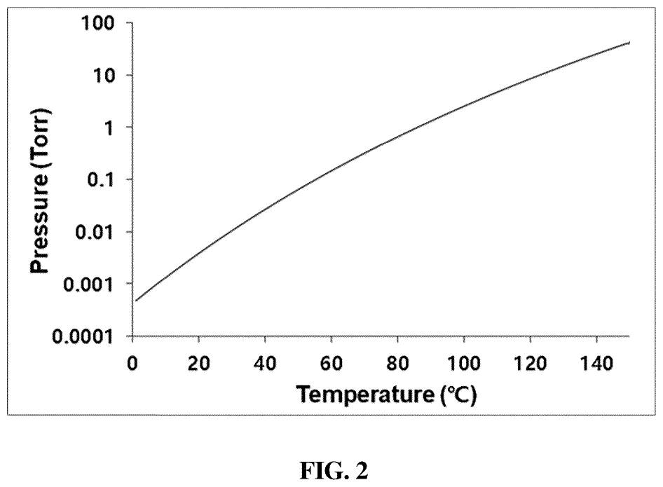

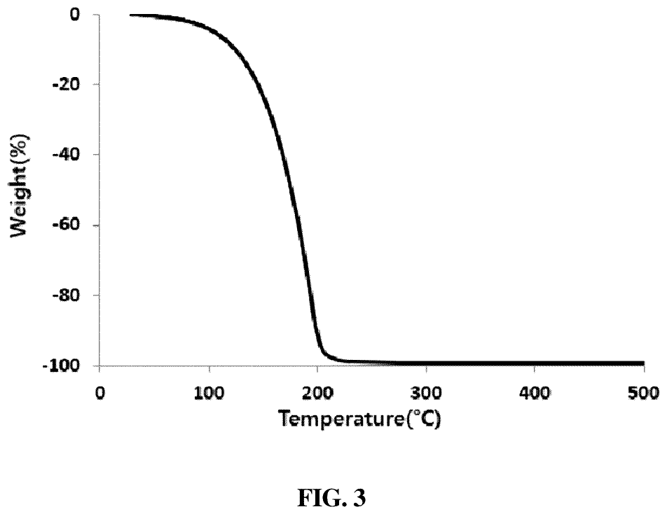

In a flame-dried 2,000 ml Schlenk flask, 1,000 ml of normal-hexane and 177.4 g (0.5 mol) of tetrakis(dimethylamino)hafnium were added and mixed under a nitrogen atmosphere. Afterward, the mixed solution was cooled to 0° C., and 59.5 g (0.55 mol) of monoethylmethylcyclophendadiene was slowly added. After the addition was completed, the reaction mixture was gradually warmed to room temperature and additionally stirred for 16 hours. After completion of the reaction, the pressure was reduced to completely remove the solvent. To increase purity, 135.8 g (yield, 65%) of the title compound in the form of a yellow liquid was obtained through distillation under reduced pressure (56° C./0.11 Torr). The results of analyzing the obtained compound through 1H-NMR are shown in FIG. 1, and the compound was confirmed to be (ethylmethylcyclopentadienyl)(trisdimethylamino)hafnium. In addition, the results of measuring the hafnium compound's vapor pressure are shown in FIG. 2, and the results of thermogravimetric analysis (TGA) are shown in FIG. 3.

### Example 2

At a silicon substrate temperature in the range of 300° C. to 370° C. (substrate temperatures of Example 2-1, 2-2, and 2-3 were at 300° C., 340° C., and 370° C., respectively), the compound of Example 1 was deposited on a substrate as a hafnium precursor in the vapor state (precursor canister temperature was at 80° C.) through atomic layer deposition to form the hafnium-containing thin film. Ozone (O₃) was used as a reaction gas, and argon (Ar) which is an inert gas was used for a purging purpose. Table 1 below shows a specific method of depositing the hafnium-containing thin film.

### Comparative Example 1

As a comparison compound, [(cyclopentadienyl)(trisdimethylamino)hafnium] was deposited on the silicon substrate to form the hafnium-containing thin film. Table 1 below shows the specific method of depositing the hafnium-containing thin film of Comparative Example 1.

TABLE 1

| | | Precursor | Purge (Ar) | | Reaction Gas | | | | | |
|---|---|---|---|---|---|---|---|---|---|---|
| | Substrate | Injection | | Thin Film | Injection (O₃) | | Purge (Ar) | | Deposition | Thin Film |
| | Temperature | Time | Flux | Thickness | Flux | Time | Flux | Time | Number | Thickness |
| | (° C.) | (sec) | (sccm) | (nm) | (g/m³) | (sec) | (sccm) | (sec) | (cycle) | (nm) |
| Example 2-1 | 300 | 5 | 1200 | 20 | 220 | 10 | 1200 | 20 | 100 | 11.25 |
| Example 2-2 | 340 | 5 | 1200 | 20 | 220 | 10 | 1200 | 20 | 100 | 11.35 |
| Example 2-3 | 370 | 5 | 1200 | 20 | 220 | 10 | 1200 | 20 | 100 | 10.50 |
| Comparative | 300 | 5 | 1200 | 20 | 220 | 10 | 1200 | 20 | 100 | 9.40 |
| Example 1 | | | | | | | | | | |

The hafnium-containing thin films deposited in Examples 2-1 to 2-3 showed a higher deposition rate than the hafnium-containing thin films deposited in Comparative Example 1.

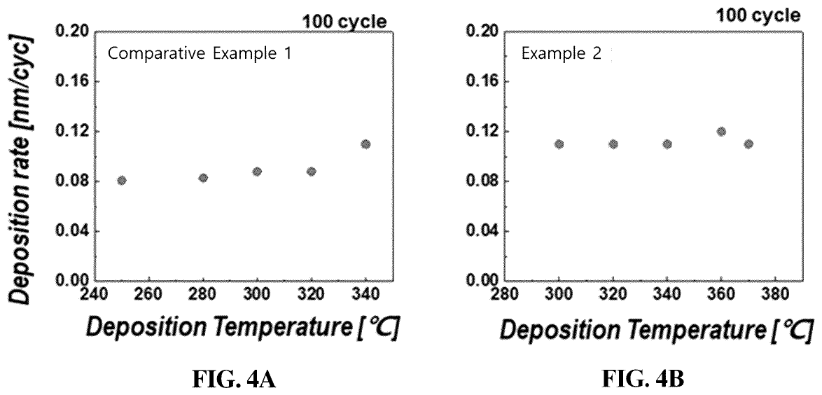

In addition, thermal decomposition occurred at around 340° C. during the hafnium-containing deposition process which used the compound of Comparative Example 1 in FIGS. 4A-4B, but the hafnium-containing thin films of Examples 2-1 to 2-3 were deposited at a temperature in the range (ALD Window) of 370° C. or higher, which meant a stable atomic layer deposition process. Therefore, the compound of Example 1 showed much higher thermal stability than the compound of Comparative Example 1.

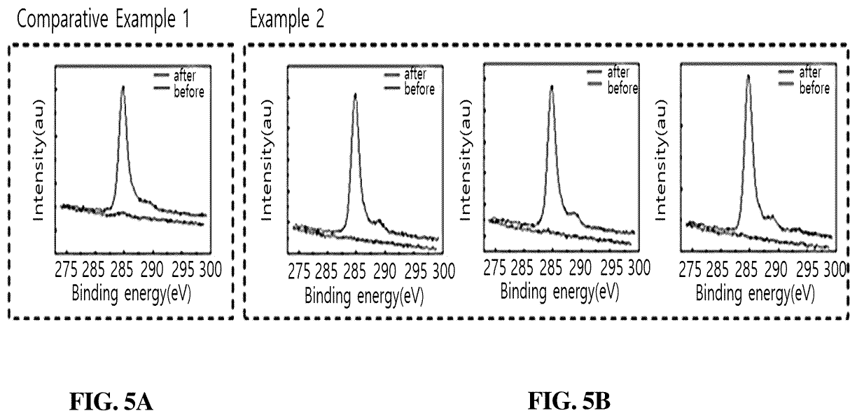

In addition, FIGS. 5A-5B showed that the hafnium-containing thin films deposited in Examples 2-1 to 2-3 had higher purity with almost no carbon content in the total than Comparative Example 1.

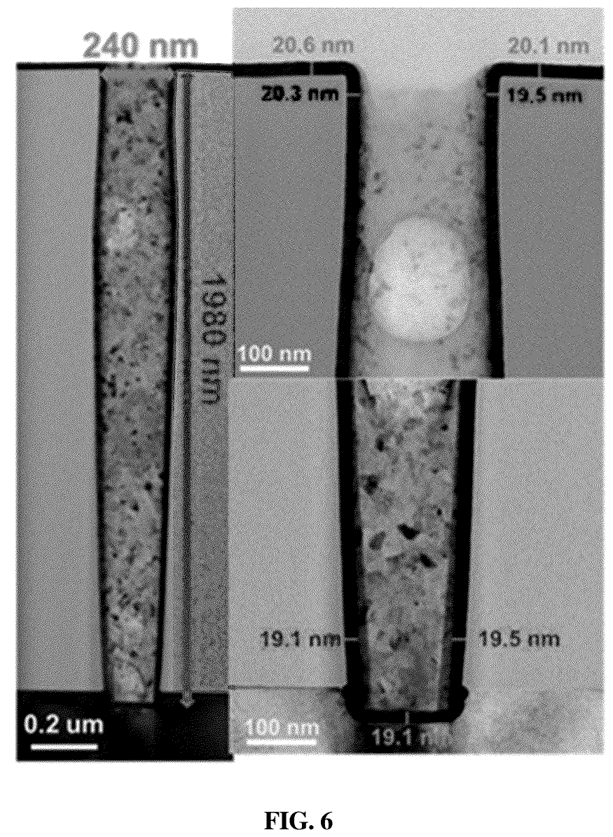

Additionally, FIG. 6 showed that the hafnium-containing thin film deposited in Examples 2-3 had very excellent thickness uniformity.

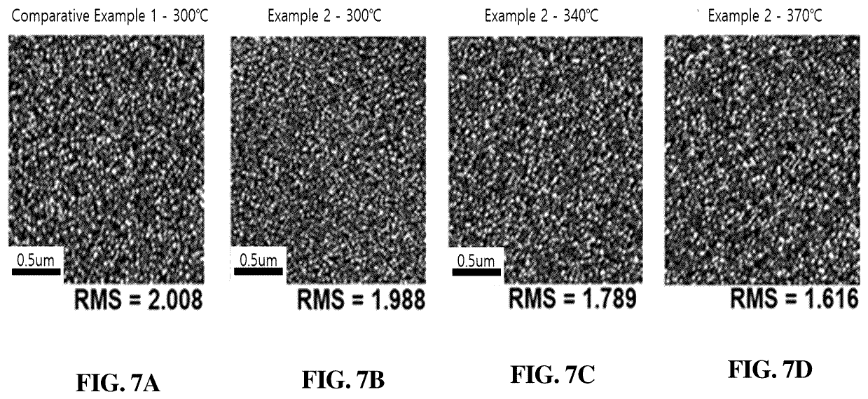

In addition, FIGS. 7A-7D showed that the hafnium thin films deposited in Examples 2-1 to 2-3 were highly densified so that the films had a flatter shape than the shape of the hafnium-containing thin film deposited in Comparative Example 1.

The present disclosure has been described with reference to preferred examples as described above but is not limited to the examples, and may be modified in various ways by those skilled in the art without departing from the spirit of the disclosure and may be changed. Such modifications and variations should be construed to fall within the scope of the present disclosure and the appended claims.

1. A hafnium compound represented by the following Formula 1, 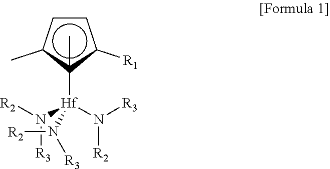
wherein in Formula 1, R₁ is an amino group, a silyl group, an alkoxy group, or a C2-C5 alkyl group, and R₂ and R₃ are each independently an amino group, a silyl group, an alkoxy group, or a C1-C5 alkyl group.

2. The hafnium compound of claim 1, wherein Formula 1 is represented by any one of the following compounds.

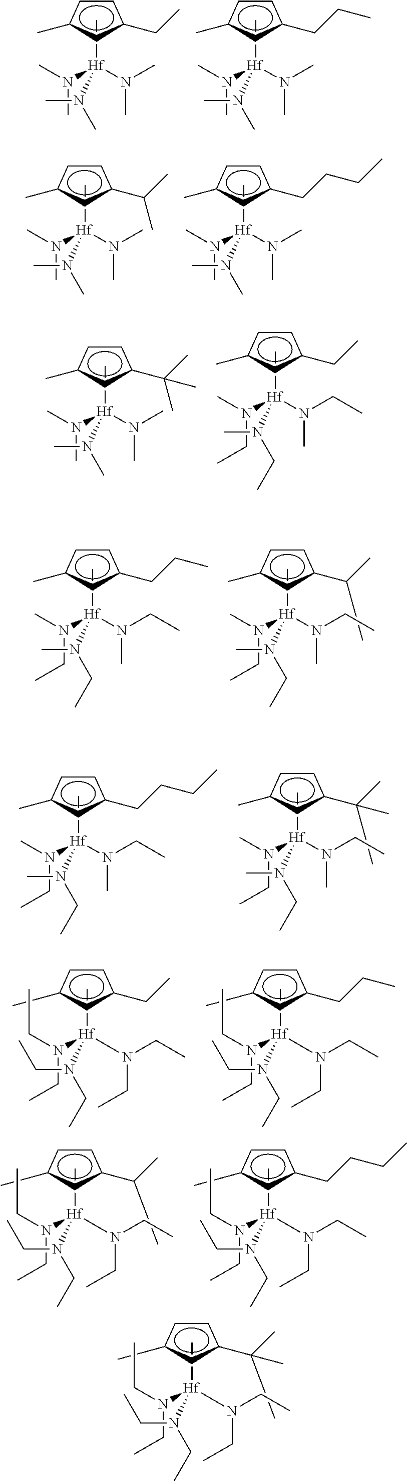

3. A hafnium-containing precursor composition comprising the hafnium compound of claim 1.

4. The hafnium-containing precursor composition of claim 3 comprising 0.1% to 99.9% by weight of a solvent, wherein the solvent is one or more organic compounds selected from unsaturated hydrocarbons, cyclic ethers, acyclic ethers, esters, alcohols, cyclic amines, acyclic amines, cyclicsulfides, acyclic sulfides, phosphines, beta-diketones, and beta-ketoesters.

5. A hafnium-containing thin film formed by using the hafnium compound of claim 1.

6. A method of forming the hafnium-containing thin film by using the hafnium compound of claim 1.

7. The method of claim 6, wherein the thin film is formed by depositing the hafnium compound or the hafnium-containing precursor composition on a substrate, and the deposition is performed through any one of a plasma-enhanced chemical vapor deposition process, a thermal chemical vapor deposition process, a plasma-enhanced atomic layer deposition, and a thermal atomic layer deposition.

8. The method of claim 7, further comprising depositing a metal-containing precursor different from the hafnium compound or the hafnium-containing precursor composition on the substrate.

9. The method of claim 7, further comprising depositing a metal-containing precursor different from the hafnium compound or the hafnium-containing precursor composition on the substrate.

10. The method of claim 8, wherein the hafnium-containing thin film comprises one or more materials of HfO2, HfZrOx, HfTiOx, and HfAOx, wherein the A is one or more of Sc, Y, La, Ac, V, Nb, Ta, Al, Ga, In, Si, Ge, Sn, and Pb.

11. The method of claim 7, wherein the substrate comprises one or a combination of titanium nitride, titanium, boron nitride, molybdenum sulfide, molybdenum, zinc oxide, tungsten, copper, aluminum oxide, tantalum nitride, niobium nitride, silicon, silicon oxide, titanium oxide, and strontium oxide.

12. The method of claim 7, wherein the substrate has a temperature in a range of 100° C. to 800° C. during the deposition.

13. The method of claim 7, wherein during the deposition, any one or a gaseous mixture of O2, O3, H2O, NO, NO2, N2O, H2O2, H2, NH3, alkylamine, hydrazine derivative, SiH4, Si2H6, BH3, B2H6, amine-borane complex, GeH4, and PH3 is used as a reaction gas.
